(19) United States
(12) Patent Application Publication
(10) Pub. No.: US 2026/0190459 A1
(43) Pub. Date: Jul. 2, 2026

(54) AREA SELECTIVE DEPOSITION OF EPI ISOLATION ENABLING FIN PITCH SCALING

(71) Applicant: Intel Corporation, Santa Clara, CA (US)

(72) Inventors: Sudipto Naskar, Portland, OR (US); Seung Hoon Sung, Portland, OR (US); Sean Pursel, Tigard, OR (US); Wen-Hsi Huang, Portland, OR (US); Mithun Ghosh, Hillsboro, OR (US); Corey Joiner, Beaverton, OR (US); Chun-Kuo Huang, Portland, OR (US); Minwoo Jung, Happy Valley, OR (US); Jessica Panella, Banks, OR (US)

(73) Assignee: Intel Corporation, Santa Clara, CA (US)

(21) Appl. No.: 19/002,279

(22) Filed: Dec. 26, 2024

(51) Int. Cl. H10D 84/83; H10D 84/01; H10D 84/85

(52) U.S. Cl. CPC H10D 84/83125; H10D 84/0188; H10D 84/851

(57) ABSTRACT

Integrated circuit (IC) devices having dielectric material separating adjacent source and drain bodies. An IC device may include adjacent first and second transistor structures having adjacent source or drain bodies separated by a dielectric material on first and second sidewalls of a first of the source or drain bodies (but only on the sidewall of the second source or drain body adjacent the first source or drain body). An isolation structure of a second dielectric material may be on the first dielectric material, on the first and second source or drain bodies, and between first and second contact structures on the first and second source or drain bodies. The dielectric material on first and second sidewalls of the first source or drain body may be selectively deposited (e.g., conformally) before the second source or drain body is grown.

### BACKGROUND

Integrated circuit (IC) devices are continually scaled down, driven to be smaller and smaller, but the risk of shorting (e.g., between adjacent, parallel channels and transistors) increases with every nanometer of scaling. For example, a significant scaling challenge is fin-to-fin scaling, forming transistors with adjacent, parallel channels ever closer while preventing shorts between those tightly packed channels.

Those transistors (and electrical isolations between them) are formed with increasing amounts of patterning passes (e.g., processing operations), which may increase both the risk of erosion (e.g., of spacers between source/drain epi) and the fabrication cost. Even state-of-the-art etches (for example, to restore epi isolation) face alignment and aspect-ratio challenges.

New techniques, structures, and materials are needed to improve isolations between transistors, to enable continued scaling in IC devices.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of an integrated circuit (IC) device having a dielectric material on both sides of a source or drain body, between and separating adjacent source or drain bodies, in accordance with some embodiments;

FIG. 2 is a flow chart of methods for forming adjacent source or drain bodies insulated by a dielectric layer between the bodies, in accordance with some embodiments;

FIGS. 3A, 3B, 3C, 3D, 3E, 3F, 3G, 3H, 3I, 3J, and 3K illustrate cross-sectional profile views of an IC device having a dielectric material on both sides of a source or drain body, between and separating adjacent source or drain bodies, at various stages of manufacture, in accordance with some embodiments;

FIG. 4 illustrates a diagram of an example data server machine employing an IC device having selectively deposited dielectric material separating source and drain bodies, in accordance with some embodiments; and

FIG. 5 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures, materials, and techniques are disclosed to improve isolations between source and drain bodies in integrated circuit (IC) devices.

A dielectric isolation may be selectively deposited on source and drain bodies, for example, epitaxially grown bodies in nonplanar field-effect transistors (FETs). The selectively deposited dielectric may obviate the need for expensive and difficult etches between tightly packed source and drain bodies (e.g., to form isolations). For example, a conformal dielectric isolation may be selectively deposited on p-type source and drain bodies before growing n-type source and drain bodies right next to the conformally covered p-type bodies. The conformal isolation may remove the requirement (and processing operations) for an isolation etch between the p-and n-type epi bodies. The omitted isolation etch between densely packed epi bodies would otherwise have demanding alignment and aspect-ratio criteria. The selective deposition may be instead of expensive lithographic patterning over one set of source and drain bodies and may, therefore, save time and monetary costs, including yield fallout. The novel dielectric isolation may enable close packing of adjacent transistors, e.g., with reduced pitches between transistor channels.

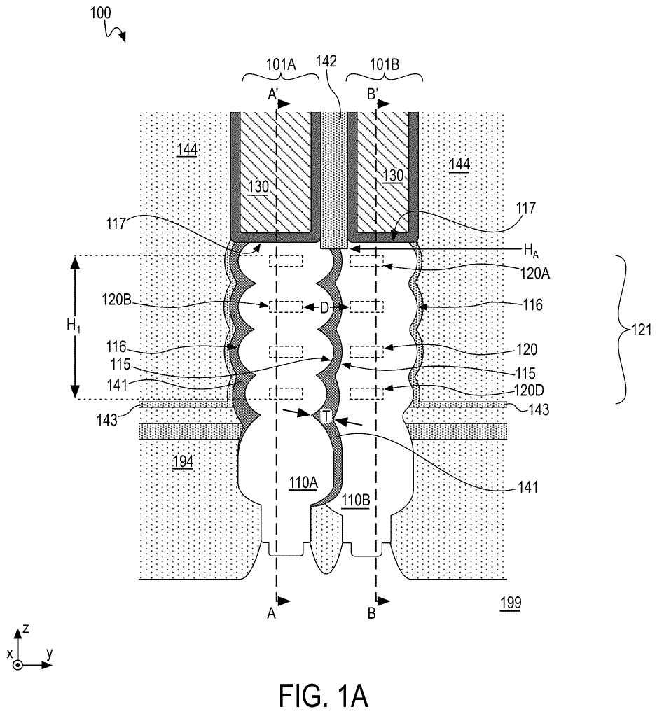

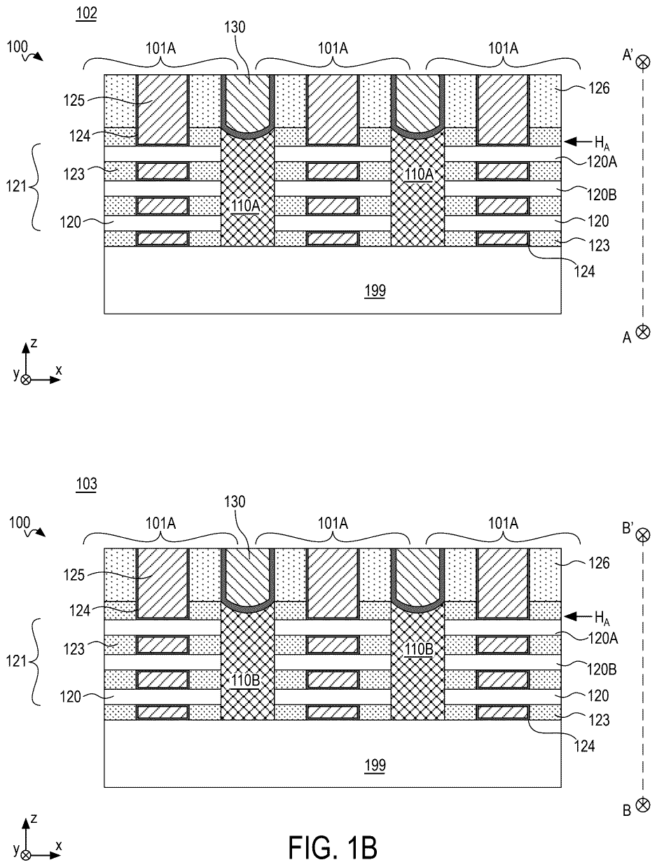

FIGS. 1A and 1B illustrate cross-sectional profile views of an IC device 100 having a dielectric material 141 on both sides of a source or drain body 110A, between and separating adjacent source or drain bodies 110A, 110B, in accordance with some embodiments. Dielectric material 141 may be conformal, for example, in layers on sidewalls 115, 116 of body 110A and sidewall 115 of body 110B. The layer of material 141 separating source or drain bodies 110 may facilitate very small pitches between channels (e.g., nanoribbons 120) of adjacent transistor structures 101A, 101B. For example, a distance D between adjacent nanoribbons 120 and structures 101A, 101B may be less than 30 nm (e.g., approximately 20 nm).

FIG. 1A shows a y-z viewing plane through adjacent bodies 110. Nanoribbons 120 coupled to source or drain bodies 110A, 110B are (in front and/or) behind bodies 110 (e.g., not in the y-z plane) and are shown with dashed lines (e.g., for reference). FIG. 1A also shows the orientation of x-z viewing planes A-A′ and B-B′ of FIG. 1B. Planes A-A′ and B-B′ are parallel (e.g., separated by more than distance D). Planes A-A′ and B-B′ are through contact structures 130; bodies 110A, 110B (respectively); stacks 121 of nanoribbons 120; and substrate 199. FIG. 1B illustrates views 102, 103 with x-z viewing planes A-A′ and B-B′ through transistor structures 101A, 101B, respectively, including source or drain bodies 110, contact structures 130, nanoribbons 120, gate electrodes 125, etc.

As shown in FIG. 1A, IC apparatus or device 100 includes first and second source or drain bodies 110A, 110B in first and second transistor structures 101A, 101B. Transistor structure 101A includes source or drain body 110A, and transistor structure 101B includes source or drain body 110B. Source or drain bodies 110A, 110B both have opposing inner and outer sides or sidewalls 115, 116. Transistor structures 101A, 101B each include a stack 121 of nanoribbons 120 (e.g., uppermost nanoribbons 120A, nanoribbons 120B immediately below nanoribbon 120A, etc.). Transistor structure 101A includes stack 121 of nanoribbons 120 coupled with source or drain body 110A. Transistor structure 101B includes stack 121 of nanoribbons 120 coupled with source or drain body 110B. Stacks 121 may include any suitable number of nanoribbons 120. Nanoribbons 120 may be of any suitable material(s), e.g., the same or different semiconductor materials in the separate stacks 121 of structures 101A, 101B.

In many embodiments, transistor structures 101A, 101B are of complementary conductivity type. For example, structure 101A may be a p-type FET, and structure 101B may be an n-type FET. In some embodiments, transistor structure 101A includes silicon germanium source or drain bodies 110A, and transistor structure 101B includes silicon source or drain bodies 110B.

Stacks 121 of nanoribbons 120 in structures 101A, 101B are separated by a distance D of less than 30 nm. In the exemplary embodiment of FIG. 1A, stacks 121 of structures 101A, 101B are separated by distance D of approximately 20 nm. The close proximity of stacks 121 may be enabled by the isolation provided by the layer of material 141. For example, distance D between stacks 121 is less than half of a height H₁ of stacks 121 (e.g., a vertical distance spanning from a bottom of lowermost nanoribbon 120D to a top of an uppermost nanoribbon 120A) in the exemplary embodiment of FIG. 1A. Without the layer of material 141 between stacks 121, forming an isolation structure between stacks 121 would require an etch with a very high aspect ratio in a very confined space, which would introduce numerous corresponding yield and/or quality and reliability risks.

Liner dielectric material 141 is on inner and outer sidewalls 115, 116 of body 110A in transistor structure 101A. The term “sidewall” (e.g., sidewalls 115, 116) may refer to curved (e.g., non-planar) surfaces and does not imply planarity or verticality. A first layer of material 141 is between source or drain bodies 110A, 110B, on inner sidewall 115 of body 110A (e.g., between the pair of bodies 110). A second layer of material 141 is on outer sidewall 116 of body 110A (e.g., external to the pair of bodies 110), opposite sidewall 115. In many embodiments, dielectric material 141 is conformal on and to source or drain body 110A, for example, as if deposited as a layer of material 141 on sidewalls 115, 116 of body 110A. In many embodiments, dielectric material 141 is conformal on and to source or drain body 110B, for example, as if body 110B was grown to abut the layer of material 141 on inner sidewall 115 of body 110A. Dielectric material 141 on body 110A and only on other materials or structures adjacent to body 110A. Dielectric material 141 is not on outer sidewall 116 of body 110B (e.g., or otherwise external to the pair of bodies 110 on the body 110B side of body 110A).

Dielectric material 141 is between source or drain bodies 110A, 110B (e.g., as a layer of material 141) and in contact with bodies 110A, 110B, on side or sidewall 115 of body 110A and on side or sidewall 115 of body 110B. In many embodiments, dielectric material 141 has a thickness T of 15 nm or less between and in contact with source or drain bodies 110A, 110B. Thinner layers of insulator material 141 may enable very tight pitches of transistor structures 101A, 101B, for example, between stacks 121. In the exemplary embodiment of FIG. 1A (with distance D of 20 nm separating stacks 121 of structures 101A, 101B), dielectric material 141 has thickness T of less than 5 nm between source or drain bodies 110A, 110B (e.g., 4 nm or less).

Dielectric material 141 is advantageously a low-permittivity (“low-k”) dielectric material, e.g., to provide superior electrical isolation (for example, with low parasitic capacitances) between source or drain bodies 110A, 110B. In many embodiments, material 141 includes silicon and oxygen (e.g., in an oxide of silicon, such as SiO₂). In some embodiments, material 141 includes one or more other elements (such as carbon and/or nitrogen), for example, to provide etch selectivities with adjacent dielectric and other materials 142, 143, 144, etc. In some such embodiments, material 141 includes carbon in an oxide of silicon. Dielectric material 141 may include any suitable material(s).

IC device 100 includes a second dielectric material 142. Dielectric material 142 provides isolation (e.g., electrical isolation) between source or drain bodies 110A, 110B (e.g., between uppermost surfaces 117 of bodies 110). Dielectric material 142 is on (e.g., in contact with) dielectric material 141 and on (e.g., in contact with) source or drain bodies 110A, 110B. Isolation material 142 contacts liner dielectric material 141 between an uppermost surface 117 of source or drain body 110A and an uppermost surface 117 of source or drain body 110B. Material 142 contacts liner material 141 below surfaces 117 of bodies 110A, 110B.

In the exemplary embodiment of FIG. 1A, isolation material 142 contacts dielectric material 141 at a height H_{A} (e.g., vertical position) above uppermost nanoribbons 120A of transistor structures 101A, 101B. The deployment of dielectric material 141 between source or drain bodies 110, on body 110A, allows for a shallow isolation (e.g., of dielectric material 142) between bodies 110. For example, without a layer of material 141 between source or drain bodies 110, an isolation of dielectric material 142 may be required to extend down entirely between bodies 110, e.g., to below lowermost nanoribbons 120 of stacks 121. In some embodiments, isolation material 142 contacts dielectric material 141 at a height H_{A} below nanoribbons 120A.

Dielectric material 142 is advantageously a low-k dielectric material, e.g., to provide superior electrical isolation (e.g., between bodies 110 and contact structures 130). In many embodiments, material 142 includes silicon and oxygen (e.g., in an oxide of silicon). In some embodiments, material 142 includes one or more other materials (e.g., elements), for example, to provide etch selectivities with adjacent materials. Dielectric material 142 may include any suitable material(s).

Dielectric material 142 provides isolation (e.g., electrical isolation) between contact structures 130 on bodies 110A, 110B. Contact structures 130 are metallization structures 130 that couple (e.g., electrically couple) bodies 110, for example, with an interconnect network (not shown) above transistor structures 101A, 101B. Dielectric material 142 is between source or drain bodies 110A, 110B and between first and second contact structures 130. Dielectric material 142 is on the layer of dielectric material 141 between bodies 110A, 110B. A first metallization structure 130 is on dielectric material 142 and on source or drain body 110A. A second metallization structure 130 is on dielectric material 142 and on source or drain body 110B.

Metallization structures 130 may include any suitable material(s), including non-metals. For example, contact structures 130 may include an interface (e.g., silicide) layer on bodies 110. Contact structures 130 may include multiple layers of metals, for example, a liner (e.g., barrier or seed) layer around a fill layer.

In many embodiments, IC device 100 includes a third dielectric material 143 to both sides of bodies 110A, 110B (e.g., outside of outer sidewalls 116). For example, in the exemplary embodiment of FIG. 1A, liner material 143 is on sidewall 116 of body 110B and on the layer of liner material 141 on sidewall 116 of body 110A.

Dielectric material 143 may be a low-k dielectric material (e.g., to provide electrical isolation) and/or a material that provides etch selectivities with adjacent materials 141, 142, 144, etc. In some embodiments, liner material 143 protects bodies 110 from material 144 (which may be or include an oxidizing material). In many embodiments, material 143 includes silicon and nitrogen (e.g., in a nitride of silicon). Dielectric material 141 may include any suitable material(s).

In many embodiments, IC device 100 includes a fourth dielectric material 144 to both sides of bodies 110A, 110B (e.g., outside of outer sidewalls 116). For example, in the exemplary embodiment of FIG. 1A, device 100 includes sections or regions of dielectric material 144 separated from dielectric material 141 and body 110B by layers of dielectric material 143. In some embodiments, dielectric material 144 is on dielectric material 141 and body 110B (and no layer of dielectric material 143 is present).

A first layer of dielectric material 143 separates a first (section or) region of dielectric material 144 from dielectric material 141 on sidewall 116 of body 110A. The first region of dielectric material 144 is on the metallization structure 130 on body 110A. The metallization structure 130 on body 110A is between the first region of dielectric material 144 and the isolation structure of dielectric material 142. A second layer of dielectric material 143 separates a second (section or) region of dielectric material 144 from sidewall 116 of body 110B. The second region of dielectric material 144 is on the metallization structure 130 on body 110B. The metallization structure 130 on body 110B is between the second region of dielectric material 144 and the isolation structure of dielectric material 142.

Device 100 may include one or more other insulator (e.g., dielectric) materials 194, etc., for example, in layers and/or trench isolations over a semiconductor portion of substrate 199. Insulator materials 194 provides isolation (e.g., electrical isolation) between adjacent structures, such as bodies 110 or between bodies 110 and a semiconductor portion of substrate 199, etc.

Substrate 199 may include any suitable material or materials. Substrate 199 may be an IC substrate, such as an IC die or wafer. In some embodiments, substrate 199 includes monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials. In many embodiments, substrate 199 includes a semiconductor material under a layer (and/or trench isolations) of insulator material 194. In some embodiments, a backside of substrate 199 is removed, e.g., to contact source or drain bodies 110, etc.

FIG. 1B illustrates pairs of adjacent transistor structures 101 (with x-z viewing plane A-A′ through structures 101A in view 102 and with x-z viewing plane B-B′ through structures 101B in view 103) over substrate 199. Nanoribbons 120 extend through gate electrodes 125, nanoribbons 120 coupled source and drain bodies 110, and contact structures 130 are on bodies 110. In view 102, transistor structures 101A include stacks 121 of nanoribbons 120 between source or drain bodies 110A. In view 103, transistor structures 101B include stacks 121 of nanoribbons 120 between source or drain bodies 110B. Dielectric material 141 (not shown) provides isolation between bodies 110A, 110B (e.g., between planes A-A′ and B-B′). Dielectric material 142 (not shown) provides isolation between contact structures 130 on bodies 110A, 110B (e.g., between planes A-A′ and B-B′). Isolation material 142 (not shown) contacts dielectric material 141 (not shown) at a height H_{A} above uppermost nanoribbons 120A of transistor structures 101A, 101B.

Source or drain bodies 110 are electrically and physically coupled to ends of nanoribbons 120 (e.g., channel regions). Source or drain bodies 110 may be impurity doped regions., e.g., regions of semiconductor material doped with one or more electrically active impurities and having increased charge-carrier availabilities and associated conductivities. Bodies 110A, 110B may be doped with an opposite type (e.g., n-or p-type) or of similar type. Source or drain bodies 110 may include a predominant semiconductor material, and one or more n-dopants (such as phosphorus, arsenic, or antimony) or p-type impurities (such as boron or aluminum). Other dopant materials may be used. Any suitable means of formation may be used. Bodies 110 may be epitaxially grown semiconductor regions, for example, of a Group IV semiconductor material (e.g., Si, Ge, SiGe, GeSn alloy). Other semiconductor materials may be employed. Bodies 110 may be substantially crystalline. Source or drain bodies 110 may be polycrystalline or substantially monocrystalline, e.g., having long-range order at least adjacent ends of nanoribbons 120 (e.g., to both sides of bodies 110) and merging or joining into a unitary body with few grain boundaries.

Source or drain bodies 110 are electrically and physically coupled to opposite ends of nanoribbons 120 (e.g., channel regions). In many embodiments, transistor structures 101 are each physically symmetrical about nanoribbons 120 (e.g., channel regions) and gate electrodes 125, and identifiers “drain” and “source” for bodies 110 may be reversed interchangeably in many contexts. However, the classification of source or drain bodies 110 may be by the electrical relationships of transistor structures 101 and bodies 110 to other components in a given circuit (e.g., and the consequent direction of current flow through structures 101 and bodies 110). Some source or drain bodies 110 may simultaneously be a source body 110 in one transistor structure 101 and a drain body 110 in another transistor structure 101.

Gate electrodes 125 are conductive (e.g., metallization structures) that couple (e.g., electrically) transistor structures 101, for example, with an interconnect network (not shown) above transistor structures 101A, 101B. Gate insulators 124 include one or more insulator materials (such as low-and high-k dielectric materials) that insulate (e.g., electrically) between nanoribbons 120 and electrode 125. In some embodiments, insulators 124 include multiple layers of dielectric materials, e.g., a low-k dielectric layer on nanoribbons 120 and a high-k dielectric layer on the low-k dielectric layer. Gate electrodes 125 and insulators 124 enable electrostatic control of conduction through channel regions of nanoribbons 120.

Spacers 123, 126 are isolation structures, e.g., of insulator material (such as a low-k dielectric), adjacent electrodes 125. Spacers 126 provide isolation between electrodes 125 and contact structures 130 (and bodies 110). Spacers 123 provide isolation between electrodes 125 and bodies 110 (and contact structures 130).

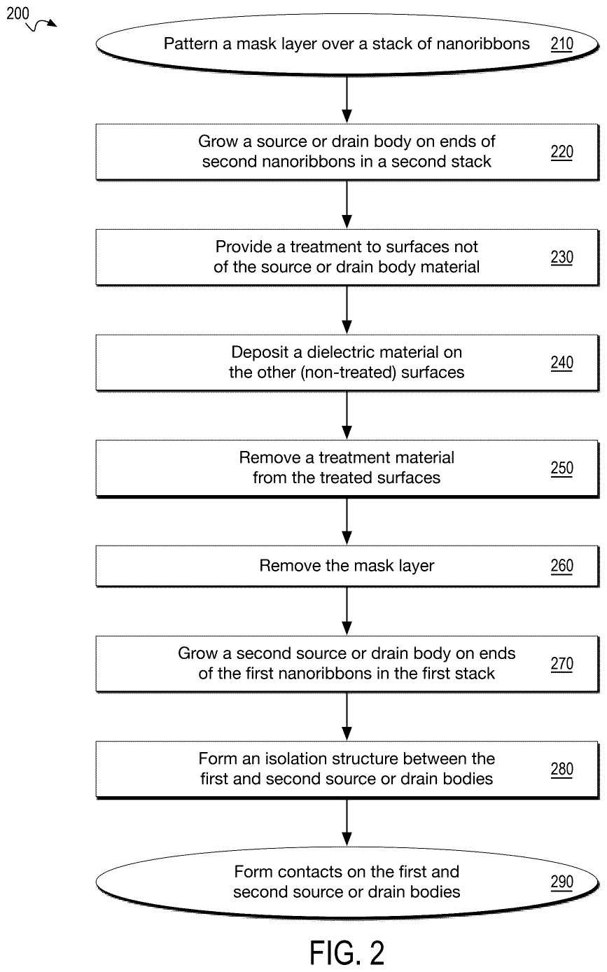

FIG. 2 is a flow chart of methods 200 for forming adjacent source or drain bodies insulated by a dielectric layer between the bodies, in accordance with some embodiments. Methods 200 include operations 210-290. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, many source or drain bodies may be grown before treating other exposed surfaces. Some operations may be included within other operations so that the number of operations illustrated FIG. 2 is not a limitation of the methods 200.

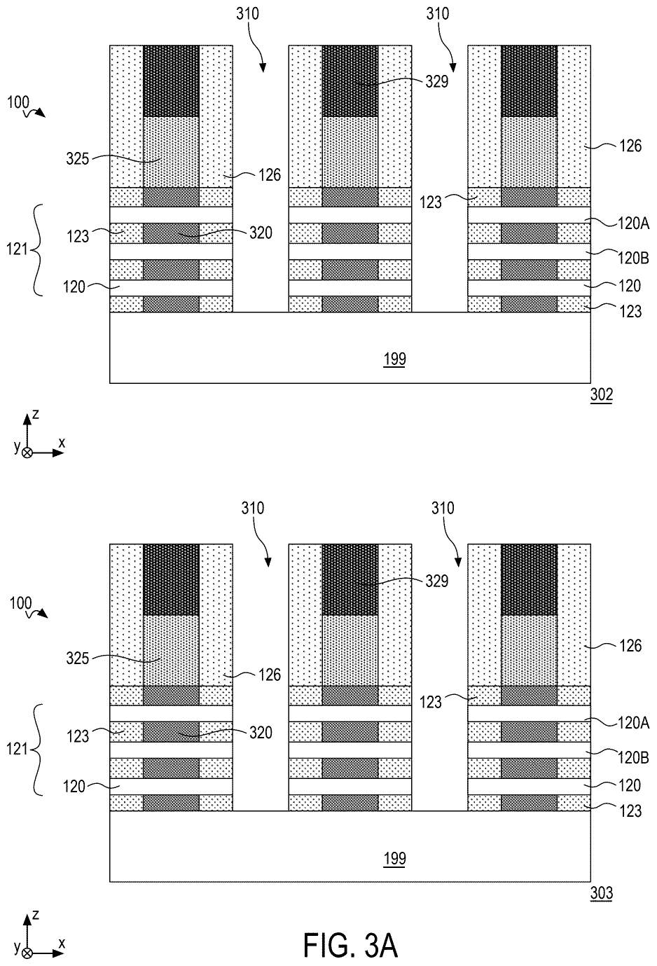

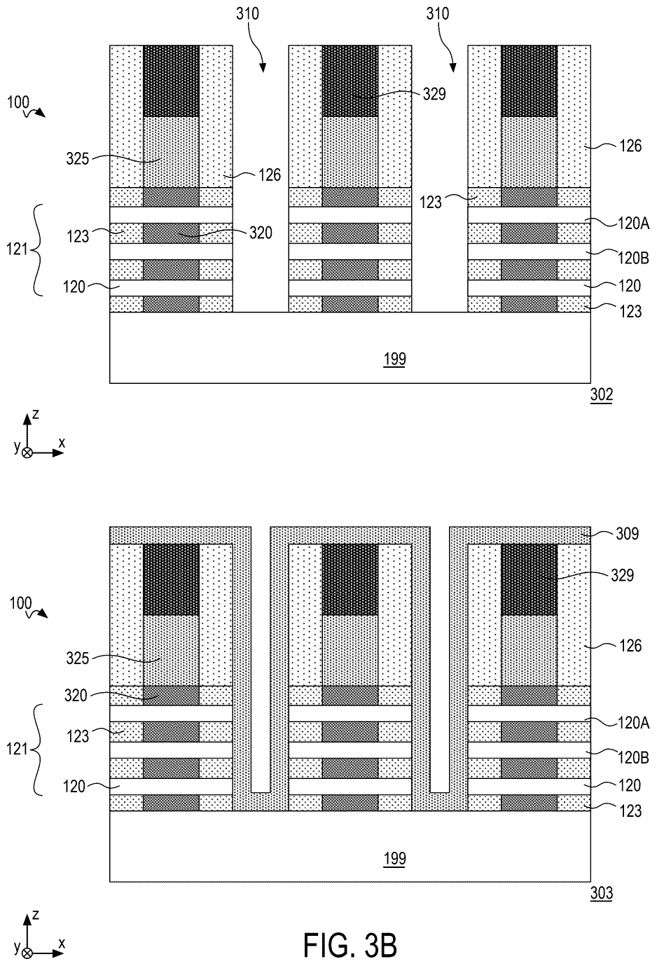

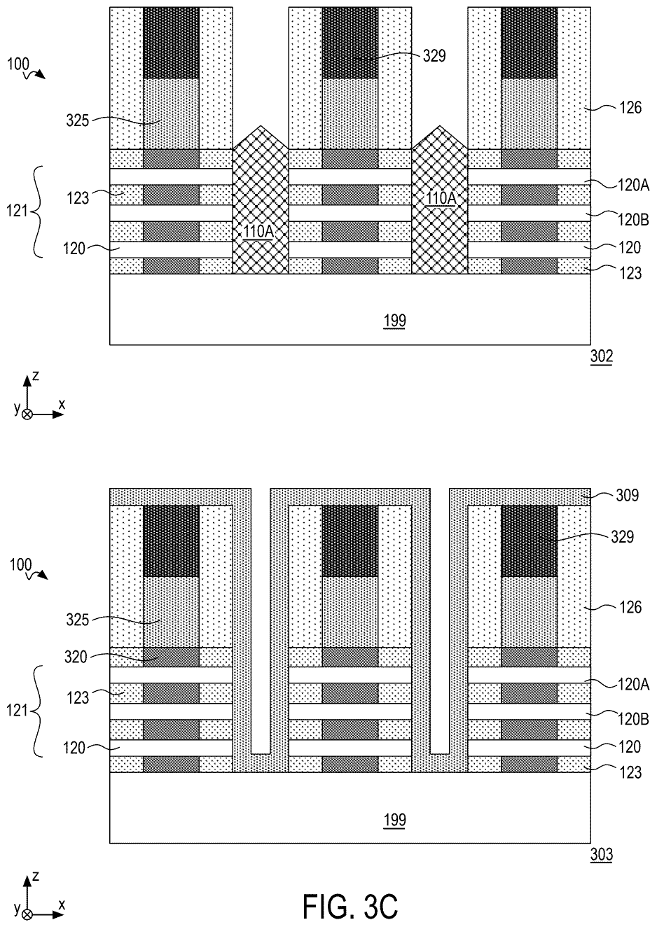

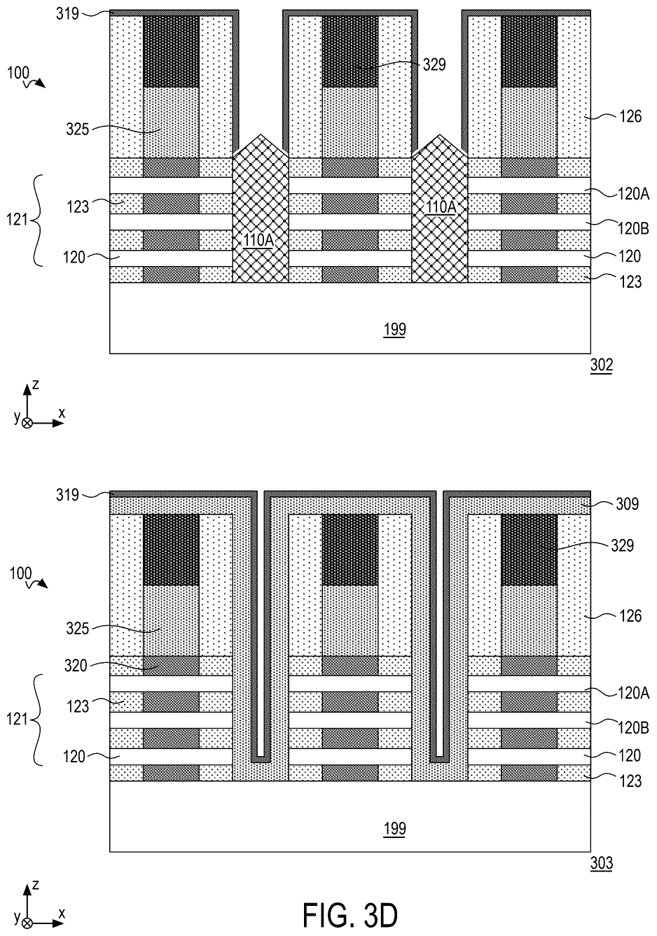

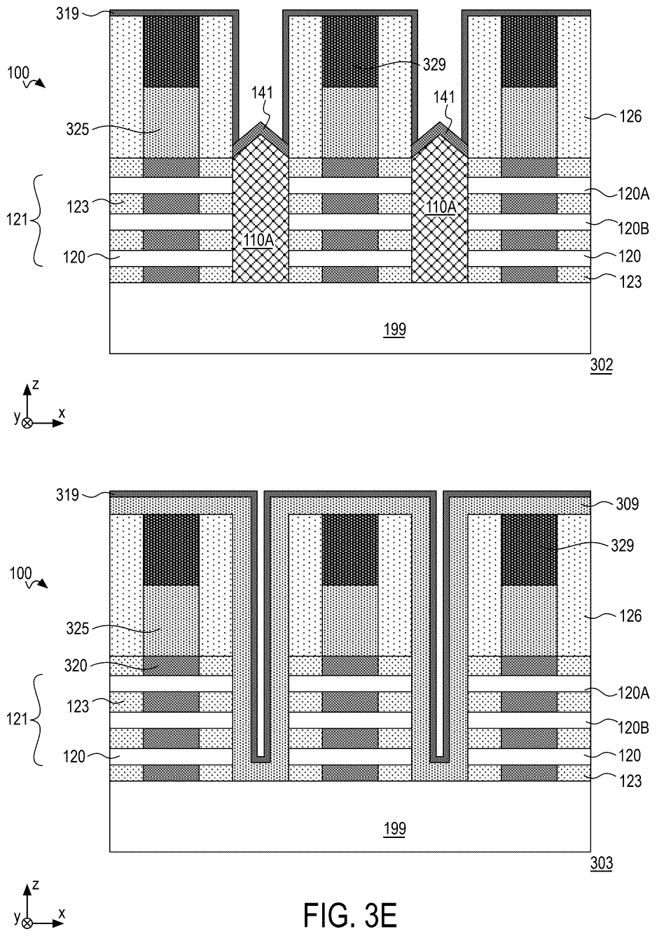

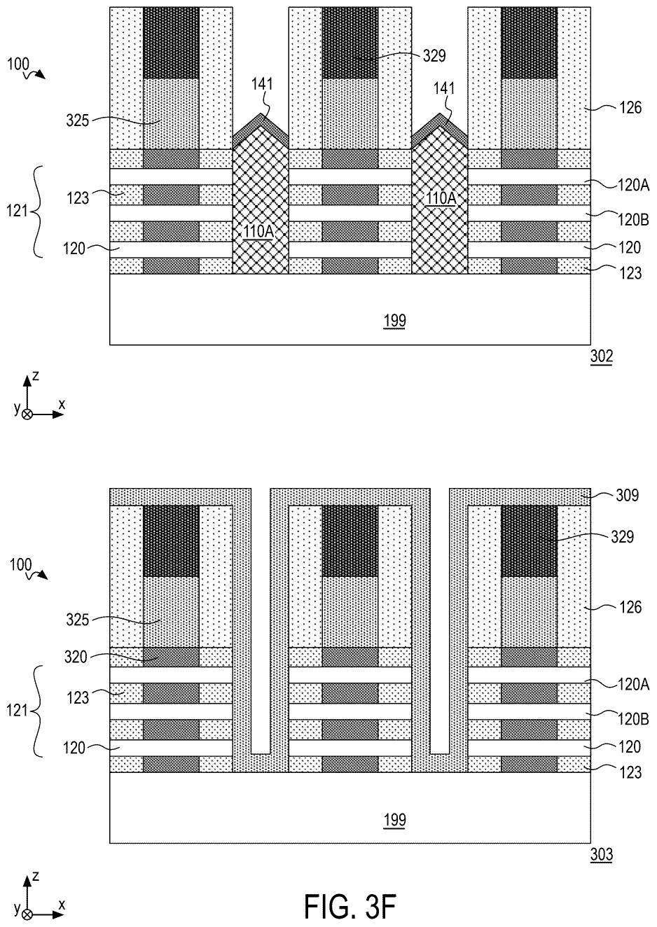

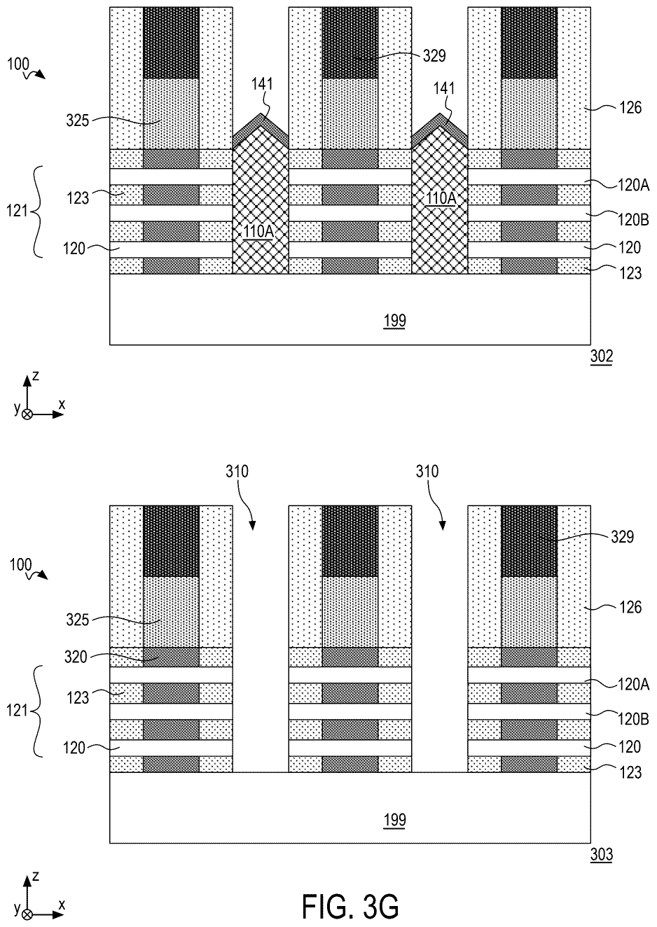

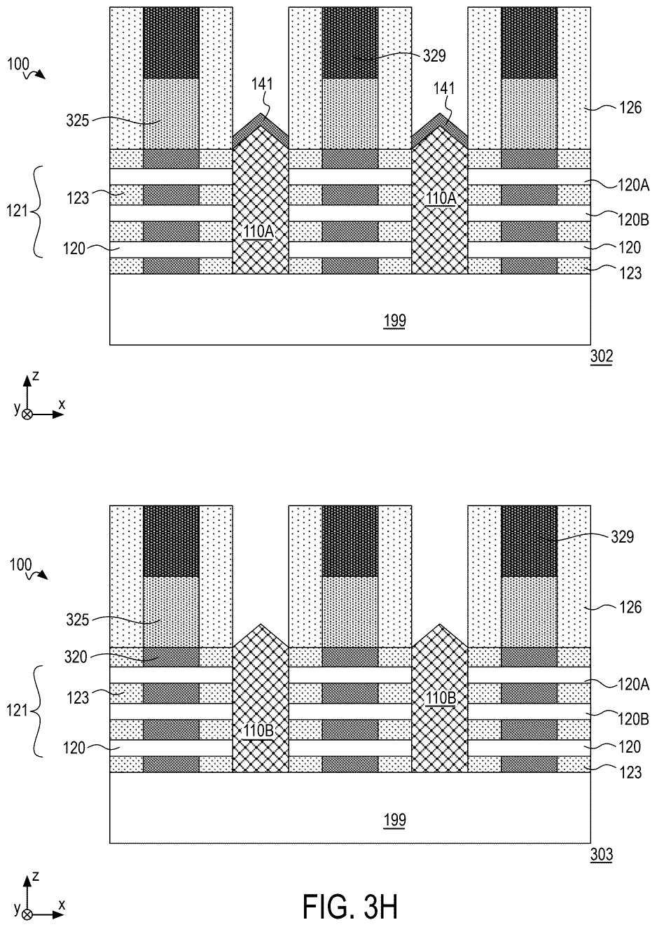

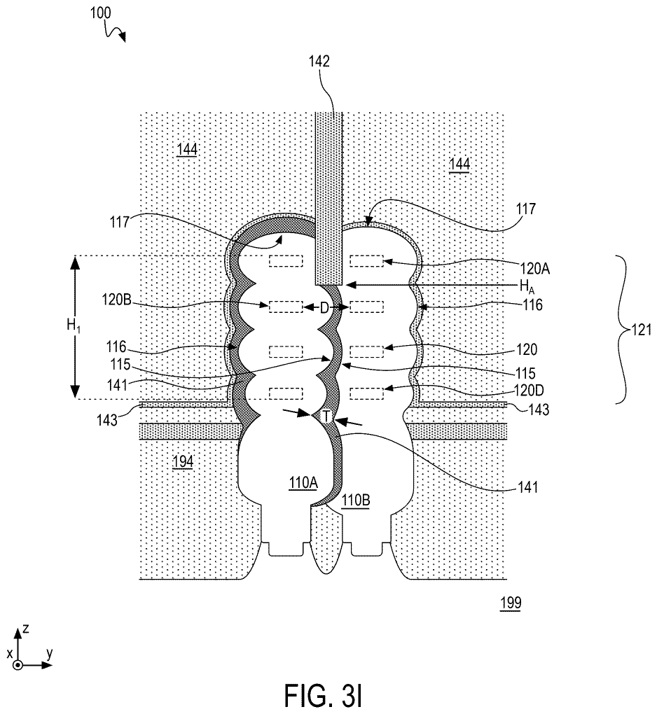

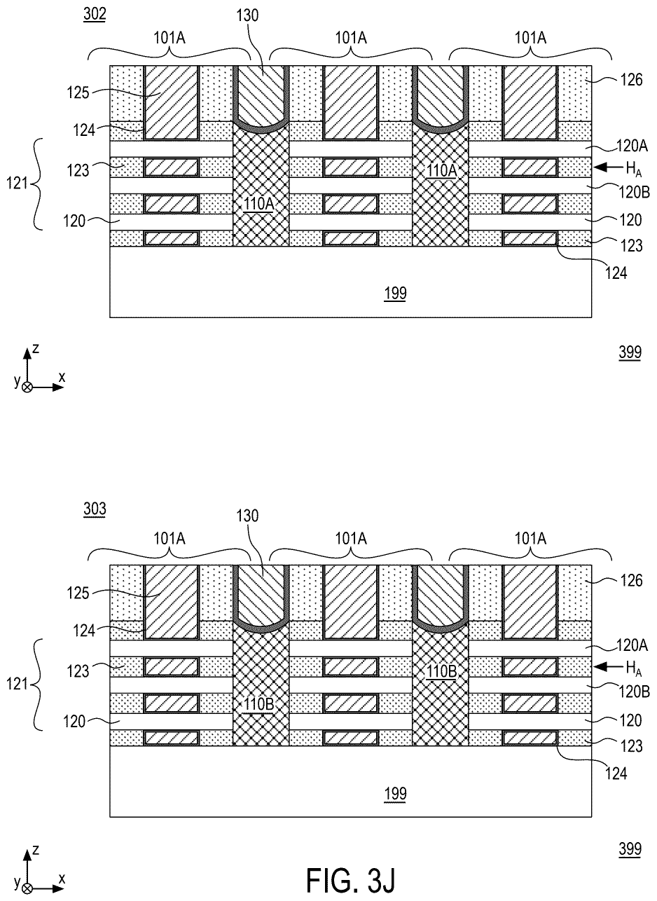

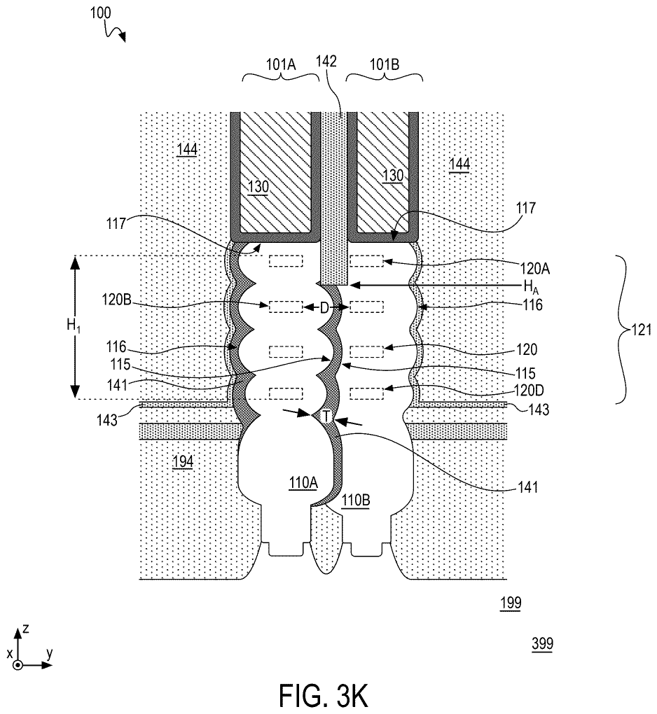

FIGS. 3A, 3B, 3C, 3D, 3E, 3F, 3G, 3H, 3I, 3J, and 3K illustrate cross-sectional profile views of IC device 100 having dielectric material 141 on both sides of source or drain body 110A, between and separating adjacent source or drain bodies 110A, 110B, at various stages of manufacture, in accordance with some embodiments. FIGS. 3A-3K show possible examples of intermediate structures during an embodiment of a practice of methods 200 of FIG. 2. Most of FIGS. 3A-3J show views 302 and 303 of (and respective parallel x-z viewing planes through) multiple inline stacks 121 of nanoribbons 120 over substrate 199 (similar to views 102 and 103 at FIG. 1B). FIGS. 3I and 3K show an orthogonal y-z viewing plane through adjacent source or drain bodies 110A, 110B (e.g., from views 102 and 103, between the stacks 121 of nanoribbons 120).

FIG. 3A shows dummy gates 325 over stacks 121 of nanoribbons 120 and substrate 199 in a workpiece or IC device 100, in accordance with some embodiments, for example, as received during a manufacturing process and prior to a performance of operation 210 of methods 200. View 302 illustrates a set of stacks 121 of nanoribbons 120 over substrate 199. View 303 shows another set of stacks 121 of nanoribbons 120 over substrate 199, adjacent to stacks 121 of view 302. The adjacent sets of stacks 121 are on parallel x-z viewing planes of views 302, 303, just in front of or behind the other, adjacent set. In many embodiments, p-type FETs will be formed incorporating nanoribbons 120 in view 302, and n-type FETs will be formed incorporating nanoribbons 120 in view 303.

Dummy (e.g., sacrificial) gate 325 is over stacks 121 of nanoribbons 120, and a hardmask 329 is over dummy gate 325. Dummy gate 325 and hardmask 329 are between spacers 126. Nanoribbons 120 (e.g., channel material layers) are between sacrificial layers 320. Ends of nanoribbons 120 are exposed in openings 310 between spacers 126.

Spacers 123 are abutting layers 320 and are vertically between nanoribbons 120. Spacers 126 are on dummy gate 325 and hardmask 329.

Returning to FIG. 2, methods 200 begin at operation 210 with patterning a mask layer. In many embodiments, the patterning the mask layer patterns the mask layer over a first stack of first nanoribbons and leaves available (e.g., exposed, revealed, etc.) a second stack of second nanoribbons, for example, the ends of the second stack of second nanoribbons. The stacks of nanoribbons may be received on or in a substrate, such as an IC die or wafer, e.g., much as described of substrate 199 at FIG. 1A. The mask layer may be patterned by any suitable means, for example, photolithographically, with photo-sensitive resist over one or more ARC (anti-reflective coating) layers, etc. The mask layer may include any suitable materials, for example, carbon, nitrogen, silicon, etc., including in compounds. In many embodiments, p-type source and drain bodies will be formed on the non-masked nanoribbons, and n-type source and drain bodies will be formed on the masked nanoribbons.

FIG. 3B illustrates both available and masked stacks 121 of nanoribbons 120 in workpiece or device 100, in accordance with some embodiments, for example, following a performance of patterning operation 210. View 302 shows the available set of stacks 121 of nanoribbons 120, not masked. View 303 illustrates the masked set of stacks 121 of nanoribbons 120, covered under mask layer 309. Ends of nanoribbons 120 in the available stacks 121 are exposed in openings 310.

Returning to FIG. 2, methods 200 continue at operation 220 with growing a source or drain body. In many embodiments, the source or drain body is grown from ends of nanoribbons (e.g., on ends of nanoribbons in an available, not-masked stack). The source or drain body may be grown by any suitable means, for example, epitaxially by a CVD (chemical vapor deposition), from each nanoribbon end and joining or merging into a unitary body between each stack of nanoribbons. In many embodiments, the grown source or drain body includes a select material (e.g., a chosen material) that is different than any other available materials. The chosen or select material may enable a subsequent selective deposition of a material onto the chosen or select material and not onto any other material surfaces or structures. In some embodiments, the grown source or drain body includes silicon germanium, and no other exposed surfaces or structures include silicon germanium. For example, in many embodiments, besides the grown source or drain body, exposed surfaces or structures include silicon, but not germanium. The grown source or drain body may include any suitable material. In many embodiments, the grown source or drain body is much as described of body 110A at FIG. 1A.

FIG. 3C shows source or drain bodies 110A (between and) on ends of nanoribbons 120 adjacent masked nanoribbons 120 in workpiece or device 100, in accordance with some embodiments, for example, following a performance of growing operation 220. View 302 illustrates bodies 110A on not-masked nanoribbons 120. In many embodiments, source or drain bodies 110A include a select or chosen material that distinguishes bodies 110A from any other exposed surfaces or structures of substrate 199 and workpiece or device 100. In some embodiments, source or drain bodies 110A include silicon germanium, and no other exposed surfaces or structures of substrate 199 and workpiece or device 100 include silicon germanium. View 303 shows the adjacent, masked set of stacks 121 of nanoribbons 120, under mask layer 309 and without source or drain bodies between nanoribbons 120.

Returning to FIG. 2, methods 200 continue by treating surfaces at operation 230. In many embodiments, the treating the surfaces treats surfaces other than the grown source or drain body. For example, the treating the surfaces provides a treatment to surfaces not having the select material of the grown source or drain body. In many embodiments, the treating the surfaces provides an organic treatment material to the surfaces receiving the treatment. In many embodiments, the treating the surfaces provides a monolayer (e.g., a self-assembled monolayer (SAM)) of a treatment material on the surfaces provided the treatment. In some embodiments, a monolayer of a treatment material is provided to surfaces not including germanium. The treatment material may be any suitable material and may be provided by any suitable means. The SAM of treatment material may inhibit subsequent deposition of dielectric material where provided. For example, SAM tail groups (e.g., including methyl groups) may cause the treated surface to be hydrophobic.

FIG. 3D illustrates a monolayer of a treatment material 319 over all surfaces of workpiece or IC device 100 except for source or drain bodies 110A, in accordance with some embodiments, for example, following a performance of treating operation 230. View 302 shows a monolayer of a treatment material 319 over all previously exposed surfaces except for bodies 110A. In many embodiments, source or drain bodies 110A include a select or chosen material that prevents the attachment of or bonding with treatment material 319. In some embodiments, source or drain bodies 110A include silicon germanium (e.g., the select material), and no other exposed surfaces or structures of substrate 199 and workpiece or device 100 include silicon germanium. View 303 illustrates a monolayer of a treatment material 319 attached to and bonded with hardmask 329. Note again that the figures are not to scale; treatment material 319 may be only a monolayer, e.g., with only a single atomic or molecular thickness.

Returning to FIG. 2, methods 200 continue with depositing a dielectric material at operation 240. In many embodiments, the depositing the dielectric material includes depositing the dielectric material on surfaces not provided the treatment (not having the treatment material), e.g., surfaces not having the select material. For example, in many embodiments, the grown source or drain body (having the select material) was not provided the treatment, does not have the treatment material, and the dielectric material is deposited selectively on the grown source or drain body (only on the grown source or drain body). The dielectric material may be deposited by any suitable means, such as CVD. The dielectric material may include any suitable material(s), such as low-k dielectric materials. The dielectric material may be much as described of dielectric material 141 at FIG. 1A.

FIG. 3E shows dielectric material 141 on bodies 110A and only on bodies 110A in workpiece or device 100, in accordance with some embodiments, for example, following a performance of depositing operation 240. View 302 illustrates dielectric material 141 on bodies 110A and not on any surfaces having treatment material 319 (e.g., all non-body 110A surfaces). View 303 shows treatment material 319 over (e.g., bonded on) all of substrate 199 and no dielectric material 141.

Returning to FIG. 2, methods 200 continue at operation 250 by removing a treatment material from the surfaces provided the treatment. The treatment material may be removed by any suitable means. In many embodiments, the treatment material is removed by a quick plasma treatment, e.g., much like a surface activation cleaning the surface by removing organic and other materials.

FIG. 3F illustrates no treatment material present in workpiece or device 100, in accordance with some embodiments, for example, following a performance of removing operation 250. View 302 shows dielectric material 141 exposed over bodies 110A. View 303 illustrates hardmask layer 309 exposed over substrate 199 (including stacks 121, etc.).

Returning to FIG. 2, methods 200 continue at operation 260 with removing the mask layer over the masked nanoribbons (e.g., the nanoribbons not coupled with the source or drain body). The mask layer may be removed by any suitable means. In many embodiments, the mask layer is removed by an isotropic or selective etch.

FIG. 3G shows no hardmask in workpiece or device 100, in accordance with some embodiments, for example, following a performance of removing operation 260. View 302 illustrates dielectric material 141 over bodies 110A. View 303 shows ends of nanoribbons 120 exposed in openings 310 and no hardmask present over substrate 199.

Returning to FIG. 2, methods 200 continue by growing a second source or drain body on nanoribbon ends at operation 270. In many embodiments, the second source or drain body is grown on ends of the nanoribbons exposed by the mask removal of operation 260. The second source or drain body may be grown by any suitable means, for example, epitaxially by a CVD. The second source or drain body may be grown much as the first source or drain body (e.g., at operation 220). In some embodiments, the second source or drain body has a composition different from the first source or drain body. For example, in many embodiments, the first source or drain body includes germanium, and the second source or drain body does not include germanium. The second source or drain body may include any suitable material. In many embodiments, the second source or drain body is much as described of body 110B at FIG. 1A.

In many embodiments, the two stacks of nanoribbons (e.g., coupled to the first and second source or drain bodies) are separated by less than 30 nm. In some such embodiments, the growing the second source or drain body grows the second source or drain body on the dielectric material deposited at operation 240. For example, the first and second source or drain bodies may be grown very closely together with only a thin layer of the deposited dielectric material separating the first and second source or drain bodies.

FIG. 3H illustrates source or drain bodies 110A, 110B with dielectric material 141 over bodies 110A in workpiece or device 100, in accordance with some embodiments, for example, following a performance of growing operation 270. View 302 shows dielectric material 141 on source or drain bodies 110A. View 303 illustrates source or drain bodies 110B coupled with nanoribbons 120. Dielectric material 141 may be on and between both of source or drain bodies 110A, 110B, e.g., between the planes of views 302, 303.

Returning to FIG. 2, methods 200 continue with forming an isolation structure between the first and second source or drain bodies at operation 280. The isolation structure may be formed by any suitable means and of any suitable material(s). The insulator material may be much as described of dielectric material 142 at FIG. 1A. In many embodiments, the isolation structure is formed by etching an opening between the first and second source or drain bodies. The etch may be any suitable etch, for example, a dry, anisotropic etch. In many embodiments, the isolation structure is formed by depositing an insulator material in the opening between the first and second source or drain bodies. The etch (and the isolation structure) need not deeply penetrate either source or drain body. The etch (and the isolation structure) need only be down to the deposited dielectric material. The insulator material may be deposited on the deposited dielectric material, for example, at a bottom of the etched opening.

The insulator material may be deposited in the opening, between the first and second source or drain bodies, and on the deposited dielectric material at any suitable depth. In many embodiments, the insulator material is deposited on the deposited dielectric material below upper surfaces of the first and second source or drain bodies. In some embodiments, the insulator material is deposited on the deposited dielectric material above the uppermost nanoribbons in the first and second stacks (e.g., coupled with the first and second source or drain bodies). In some embodiments, the insulator material is deposited on the deposited dielectric material below the uppermost nanoribbons in the first and second stacks. In some such embodiments, the insulator material is deposited on the deposited dielectric material above the nanoribbons immediately below the uppermost nanoribbons in the first and second stacks.

FIG. 3I shows adjacent source or drain bodies 110A, 110B separated by dielectric materials 141, 142 in workpiece or device 100, in accordance with some embodiments, for example, following a performance of forming operation 280. FIG. 3I has a y-z viewing plane through bodies 110A, 110B, e.g., orthogonal to the x-z viewing planes of views 302, 303 of FIGS. 3A-3H. In the exemplary embodiment of FIG. 3I), isolation material 142 contacts dielectric material 141 at a height H_{A} above second nanoribbons 120B and below uppermost nanoribbons 120A of transistor structures 101A, 101B.

Returning to FIG. 2, methods 200 continue at operation 290 by forming contacts (e.g., metallization structures) on each of the first and second source or drain bodies. The contacts may be formed by any suitable means and of any suitable material(s). The contacts may be formed by removing dielectric material from the first and second source or drain bodies and depositing conductive material on the first and second source or drain bodies (e.g., to both sides, and on both sidewalls, of the isolation structure).

The removing dielectric material from the first and second source or drain bodies includes removing the deposited dielectric material from an upper surface of the first source or drain body. The deposited dielectric material may be removed by any suitable means, such as a dry, anisotropic etch. The etch may remove the deposited dielectric material (e.g., from operation 240), as well as any other dielectric materials over the first source or drain body. A similar etch may remove any dielectric materials from over the second source or drain body.

The depositing conductive material on the first and second source or drain bodies may conformally deposit a conductive material (e.g., a metal) on an upper surface of the first source or drain body, an upper surface of the second source or drain body, and on both, opposing sidewalls of the isolation structure. The depositing conductive material may be by any suitable means, for example, a CVD. The conductive material may be of any suitable material(s), e.g., multiple layers of metals, such barrier or seed layers around a fill layer. The contact structures may be much as described of metallization structures 130 at FIG. 1A.

FIGS. 3J and 3K illustrate dielectric material 141 on both sides of a source or drain body 110A, between and separating source or drain bodies 110A, 110B of transistor structures 101A, 101B in IC device 100, in accordance with some embodiments, for example, following a performance of forming operation 290. Device 100 is coupled to a host component 399. Device 100 is coupled to a power supply (not shown) through host component 399. FIG. 3J shows view 302 with an x-z viewing plane through transistor structures 101A. FIG. 3J also illustrates view 303 with an x-z viewing plane through transistor structures 101B. FIG. 3K shows a y-z viewing plane (e.g., orthogonal to the x-z viewing planes of views 302, 303 of FIG. 3J) through a pair of adjacent bodies 110A, 110B separated by dielectric materials 141, 142. In the exemplary embodiments of FIGS. 3J and 3K, isolation material 142 contacts dielectric material 141 at a height H_{A} above nanoribbons 120B and uppermost nanoribbons 120A of transistor structures 101A, 101B.

IC device 100 may include or be coupled to a substrate or other host component 399. Host component 399 may be a package substrate, an interposer, an IC die, etc. For example, substrate 199 may be an IC die that includes transistor structures 101, substrate 199 may be coupled (e.g., soldered or otherwise bonded) to host component 399, and transistor structures 101 may be coupled to a power supply (not shown) through host component 399.

Host component 399 is a planar platform and may include dielectric and metallization structures. Host component 399 mechanically supports and electrically couples one or more IC devices 100. At least one side of host component 399 includes substrate interconnect interfaces for bonding to one or more IC devices 100. IC device 100 may be direct bonded, e.g., hybrid bonded, to host component 399 or otherwise bonded, e.g., by optional solder bumps. The opposite side of host component 399 may include similar interfaces, e.g., copper pads for socketing and/or solder bumps for bonding device 100 to a host component, such as a printed circuit board (PCB). Host component 399 may be any host component with substrate interconnect interfaces, such as a package host component 399 or interposer, etc. Host component 399 may itself be a die.

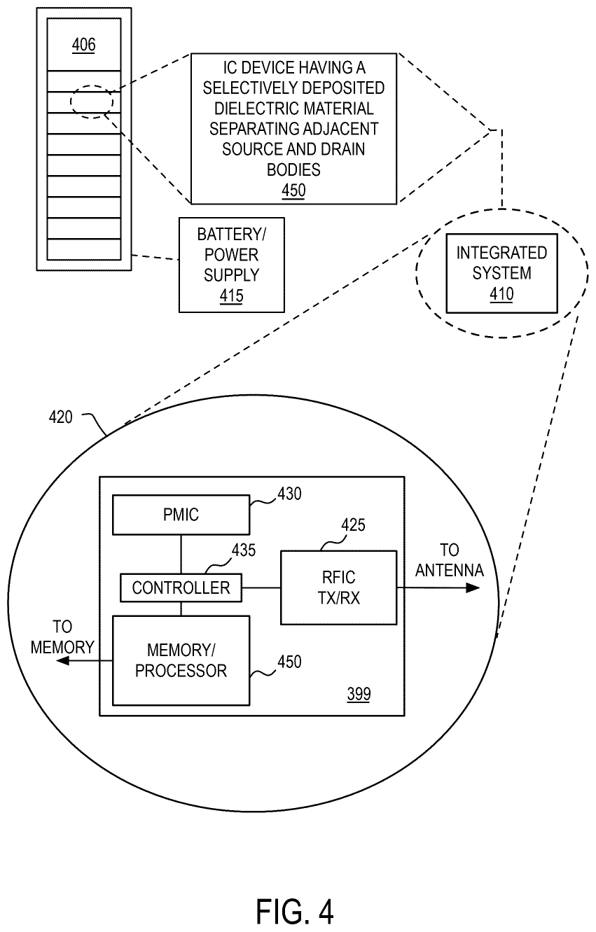

FIG. 4 illustrates a diagram of an example data server machine 406 employing an IC device having selectively deposited dielectric material separating source and drain bodies, in accordance with some embodiments. Server machine 406 may be any commercial server, for example, including any number of high-performance computing platforms disposed within a rack and networked together for electronic data processing, which in the exemplary embodiment includes one or more devices 450 having selectively deposited dielectric material separating source and drain bodies.

Also as shown, server machine 406 includes a battery and/or power supply 415 to provide power to devices 450, and to provide, in some embodiments, power delivery functions such as power regulation. Devices 450 may be deployed as part of a package-level integrated system 410. Integrated system 410 is further illustrated in the expanded view 420. In the exemplary embodiment, devices 450 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 450 is a microprocessor including a static RAM (SRAM) cache memory. As shown, device 450 may be an IC device having selectively deposited dielectric material separating source and drain bodies, as discussed herein. Device 450 may be further coupled to (e.g., communicatively coupled to) a board, an interposer, or other substrate or host component 399 along with, one or more of a power management IC (PMIC) 430, RF (wireless) IC (RFIC) 425 including a wideband RF (wireless) transmitter and/or receiver (TX/RX) (e.g., including a digital baseband and an analog front end module further includes a power amplifier on a transmit path and a low noise amplifier on a receive path), and a controller 435 thereof. In some embodiments, RFIC 425, PMIC 430, controller 435, and device 450 include having selectively deposited dielectric material separating source and drain bodies.

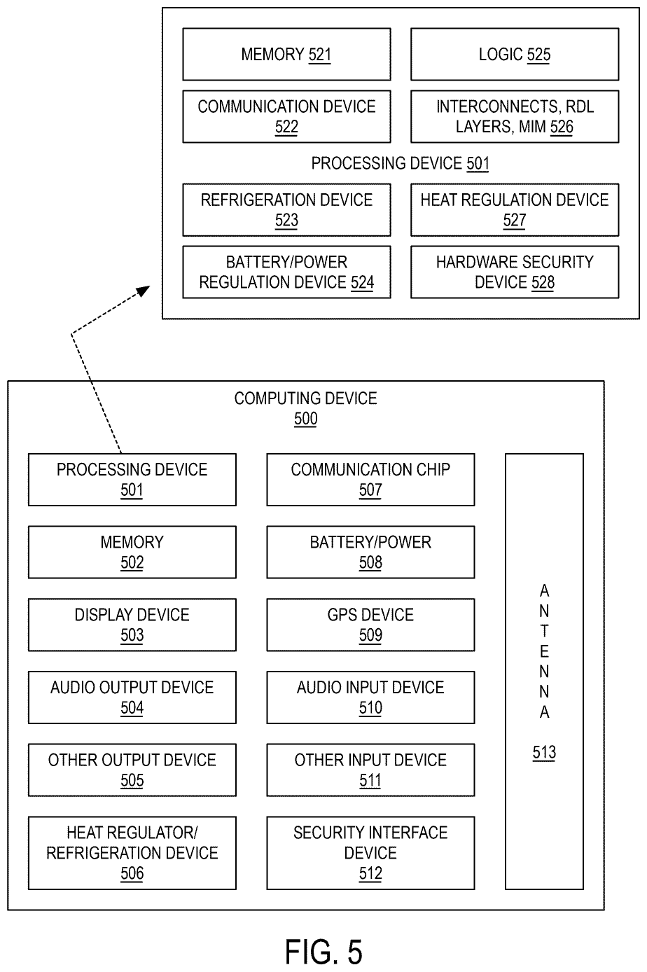

FIG. 5 is a block diagram of an example computing device 500, in accordance with some embodiments. For example, one or more components of computing device 500 may include any of the devices or structures discussed herein. A number of components are illustrated in FIG. 5 as being included in computing device 500, but any one or more of these components may be omitted or duplicated, as suitable for the application. In some embodiments, some or all of the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled. In another set of examples, computing device 500 may not include an audio output device 504, other output device 505, global positioning system (GPS) device 509, audio input device 510, or other input device 511, but may include audio output device interface circuitry, other output device interface circuitry, GPS device interface circuitry, audio input device interface circuitry, audio input device interface circuitry, to which audio output device 504, other output device 505, GPS device 509, audio input device 510, or other input device 511 may be coupled.

Computing device 500 may include a processing device 501 (e.g., one or more processing devices). As used herein, the term “processing device” or “processor” indicates a device that processes electronic data from registers and/or memory to transform that electronic data into other electronic data that may be stored in registers and/or memory. Processing device 501 may include a memory 521, a communication device 522, a refrigeration device 523, a battery/power regulation device 524, logic 525, interconnects 526 (i.e., optionally including redistribution layers (RDL) or metal-insulator-metal (MIM) devices), a heat regulation device 527, and a hardware security device 528.

Processing device 501 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 500 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 502 includes memory that shares a die with processing device 501. This memory may be used as cache memory and may include embedded dynamic random-access memory (eDRAM) or spin transfer torque magnetic random-access memory (STT-MRAM).

Computing device 500 may include a heat regulation/refrigeration device 506. Heat regulation/refrigeration device 506 may maintain processing device 501 (and/or other components of computing device 500) at a predetermined low temperature during operation.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a GPS device 509 (or corresponding interface circuitry, as discussed above). GPS device 509 may be in communication with a satellite-based system and may receive a location of computing device 500, as known in the art.

Computing device 500 may include other output device 505 (or corresponding interface circuitry, as discussed above). Examples of the other output device 505 may include an audio codec, a video codec, a printer, a wired or wireless transmitter for providing information to other devices, or an additional storage device.

Computing device 500 may include other input device 511 (or corresponding interface circuitry, as discussed above). Examples of the other input device 511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, access list management, malware detection, or spyware detection.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-5. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first source or drain body in a first transistor structure, the first source or drain body including opposing first and second sides, a first dielectric material on the first and second sides, a second source or drain body in a second transistor structure, the first dielectric material between the first and second source or drain bodies on the first side of the first source or drain body and on a third side of the second source or drain body, a second dielectric material on the first dielectric material and on the first and second source or drain bodies, and first and second metallization structures, the first metallization structure on the second dielectric material and the first source or drain body, the second metallization structure on the second dielectric material and the second source or drain body.

In one or more second embodiments, further to the first embodiments, the first transistor structure includes a first stack of nanoribbons coupled with the first source or drain body, the second transistor structure includes a second stack of nanoribbons coupled with the second source or drain body, and the first and second stacks of nanoribbons are separated by less than 30 nm.

In one or more third embodiments, further to the first or second embodiments, a layer of the first dielectric material is between the first and second source or drain bodies, on the first side of the first source or drain body, and on the third side of the second source or drain body, and the layer of the first dielectric material has a thickness of less than 5 nm, and the first and second stacks of nanoribbons are separated by 20 nm or less.

In one or more fourth embodiments, further to the first through third embodiments, the second dielectric material contacts the first dielectric material between and below a first uppermost surface of the first source or drain body, and a second uppermost surface of the second source or drain body, and the second dielectric material contacts the first dielectric material above an uppermost one of the first stack of nanoribbons, and an uppermost one of the second stack of nanoribbons.

In one or more fifth embodiments, further to the first through fourth embodiments, the first dielectric material has a thickness of 15 nm or less between and in contact with the first and second source or drain bodies.

In one or more sixth embodiments, further to the first through fifth embodiments, the first dielectric material has the thickness of 5 nm or less between the first and second source or drain bodies.

In one or more seventh embodiments, further to the first through sixth embodiments, the apparatus also includes a third dielectric material on the first dielectric material on the second side of the first source or drain body and on a fourth side of the second source or drain body, the fourth side opposite the third side.

In one or more eighth embodiments, further to the first through seventh embodiments, the apparatus also includes first and second regions of a fourth dielectric material, wherein a first layer of the third dielectric material separates the first region of the fourth dielectric material and the first dielectric material on the second side of the first source or drain body, and a second layer of the third dielectric material separates the second region of the fourth dielectric material and the fourth side of the second source or drain body.

In one or more ninth embodiments, further to the first through eighth embodiments, the first region of the fourth dielectric material is on the first metallization structure, the first metallization structure is between the first region of the fourth dielectric material and the second dielectric material, the second region of the fourth dielectric material is on the second metallization structure, and the second metallization structure is between the second region of the fourth dielectric material and the second dielectric material.

In one or more tenth embodiments, an apparatus includes first and second source or drain bodies in first and second transistor structures, first and second layers of a first dielectric material, the first layer between the first and second source or drain bodies and on a first sidewall of the first source or drain body, the second layer on a second sidewall of the first source or drain body, opposite the first sidewall, first and second metallization structures, the first metallization structure on the first source or drain body, the second metallization structure on the second source or drain body, and a second dielectric material, between the first and second source or drain bodies, between the first and second metallization structures, and on the first layer of the first dielectric material.

In one or more eleventh embodiments, further to the tenth embodiments, the first transistor structure includes a first stack of nanoribbons coupled with the first source or drain body, the second transistor structure includes a second stack of nanoribbons coupled with the second source or drain body, and the first and second stacks of nanoribbons are separated by less than 30 nm.

In one or more twelfth embodiments, further to the tenth or eleventh embodiments, the first layer of the first dielectric material has a thickness of 15 nm or less between and in contact with the first and second source or drain bodies.

In one or more thirteenth embodiments, further to the tenth through twelfth embodiments, the apparatus also includes a third dielectric material on the second layer of the first dielectric material and on a third sidewall of the second source or drain body.

In one or more fourteenth embodiments, further to the tenth through thirteenth embodiments, the apparatus also includes first and second sections of a fourth dielectric material, wherein a third layer of the third dielectric material separates the first section of the fourth dielectric material and the second layer of the first dielectric material on the second sidewall of the first source or drain body, the first section of the fourth dielectric material is on the first metallization structure, the first metallization structure is between the first section of the fourth dielectric material and the second dielectric material, a fourth layer of the third dielectric material separates the second section of the fourth dielectric material and the third sidewall of the second source or drain body, the second section of the fourth dielectric material is on the second metallization structure, and the second metallization structure is between the second section of the fourth dielectric material and the second dielectric material.

In one or more fifteenth embodiments, further to the tenth through fourteenth embodiments, the apparatus is coupled to a host component, and the apparatus is coupled to a power supply through the host component.

In one or more sixteenth embodiments, a method includes patterning a mask layer over a first stack of first nanoribbons, growing a first source or drain body on ends of second nanoribbons in a second stack, the first source or drain body including a select material, providing a treatment to surfaces not including the select material, depositing a dielectric material on surfaces including the select material and not provided the treatment, including on surfaces of the first source or drain body, removing a treatment material from the surfaces provided the treatment, removing the mask layer over the first nanoribbons, and growing a second source or drain body on ends of the first nanoribbons.

In one or more seventeenth embodiments, further to the sixteenth embodiments, the first stack of first nanoribbons and the second stack of second nanoribbons are separated by less than 30 nm, and the growing the second source or drain body on the ends of the first nanoribbons grows the second source or drain body to the deposited dielectric material, the first and second source or drain bodies separated by the deposited dielectric material.

In one or more eighteenth embodiments, further to the sixteenth or seventeenth embodiments, the method also includes forming an isolation structure between the first and second source or drain bodies by etching an opening between the first and second source or drain bodies, and depositing an insulator material in the opening between the first and second source or drain bodies, the insulator material on the deposited dielectric material.

In one or more nineteenth embodiments, further to the sixteenth through eighteenth embodiments, the depositing the insulator material in the opening between the first and second source or drain bodies deposits the insulator material on the deposited dielectric material below a first upper surface of the first source or drain body, below a second upper surface of the second source or drain body, above a first one of the first nanoribbons immediately below an uppermost one of the first nanoribbons, and above a first one of the second nanoribbons immediately below an uppermost one of the second nanoribbons.

In one or more twentieth embodiments, further to the sixteenth through nineteenth embodiments, the method also includes forming first and second contacts on the first and second source or drain bodies by removing the deposited dielectric material from an upper surface of the first source or drain body, depositing a metal on the upper surface of the first source or drain body and on a first sidewall of the isolation structure, and depositing the metal on an upper surface of the second source or drain body and on a second sidewall of the isolation structure, the second sidewall opposite the first sidewall.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first source or drain body in a first transistor structure, the first source or drain body comprising opposing first and second sides;
a first dielectric material on the first and second sides;
a second source or drain body in a second transistor structure, the first dielectric material between the first and second source or drain bodies on the first side of the first source or drain body and on a third side of the second source or drain body;
a second dielectric material on the first dielectric material and on the first and second source or drain bodies; and
first and second metallization structures, the first metallization structure on the second dielectric material and the first source or drain body, the second metallization structure on the second dielectric material and the second source or drain body.

2. The apparatus of claim 1, wherein:
the first transistor structure comprises a first stack of nanoribbons coupled with the first source or drain body;
the second transistor structure comprises a second stack of nanoribbons coupled with the second source or drain body; and
the first and second stacks of nanoribbons are separated by less than 30 nm.

3. The apparatus of claim 2, wherein:
a layer of the first dielectric material is:
between the first and second source or drain bodies;
on the first side of the first source or drain body; and
on the third side of the second source or drain body; and
the layer of the first dielectric material has a thickness of less than 5 nm; and
the first and second stacks of nanoribbons are separated by 20 nm or less.

4. The apparatus of claim 2, wherein:
the second dielectric material contacts the first dielectric material between and below:
a first uppermost surface of the first source or drain body; and
a second uppermost surface of the second source or drain body; and
the second dielectric material contacts the first dielectric material above:
an uppermost one of the first stack of nanoribbons; and
an uppermost one of the second stack of nanoribbons.

5. The apparatus of claim 1, wherein the first dielectric material has a thickness of 15 nm or less between and in contact with the first and second source or drain bodies.

6. The apparatus of claim 5, wherein the first dielectric material has the thickness of 5 nm or less between the first and second source or drain bodies.

7. The apparatus of claim 1, further comprising a third dielectric material on the first dielectric material on the second side of the first source or drain body and on a fourth side of the second source or drain body, the fourth side opposite the third side.

8. The apparatus of claim 7, further comprising first and second regions of a fourth dielectric material, wherein:
a first layer of the third dielectric material separates the first region of the fourth dielectric material and the first dielectric material on the second side of the first source or drain body; and
a second layer of the third dielectric material separates the second region of the fourth dielectric material and the fourth side of the second source or drain body.

9. The apparatus of claim 8, wherein:
the first region of the fourth dielectric material is on the first metallization structure;
the first metallization structure is between the first region of the fourth dielectric material and the second dielectric material;
the second region of the fourth dielectric material is on the second metallization structure; and
the second metallization structure is between the second region of the fourth dielectric material and the second dielectric material.

10. An apparatus, comprising:
first and second source or drain bodies in first and second transistor structures;
first and second layers of a first dielectric material, the first layer between the first and second source or drain bodies and on a first sidewall of the first source or drain body, the second layer on a second sidewall of the first source or drain body, opposite the first sidewall;
first and second metallization structures, the first metallization structure on the first source or drain body, the second metallization structure on the second source or drain body; and
a second dielectric material, between the first and second source or drain bodies, between the first and second metallization structures, and on the first layer of the first dielectric material.

11. The apparatus of claim 10, wherein:
the first transistor structure comprises a first stack of nanoribbons coupled with the first source or drain body;
the second transistor structure comprises a second stack of nanoribbons coupled with the second source or drain body; and
the first and second stacks of nanoribbons are separated by less than 30 nm.

12. The apparatus of claim 11, wherein the first layer of the first dielectric material has a thickness of 15 nm or less between and in contact with the first and second source or drain bodies.

13. The apparatus of claim 12, further comprising a third dielectric material on the second layer of the first dielectric material and on a third sidewall of the second source or drain body.

14. The apparatus of claim 13, further comprising first and second sections of a fourth dielectric material, wherein:
a third layer of the third dielectric material separates the first section of the fourth dielectric material and the second layer of the first dielectric material on the second sidewall of the first source or drain body;
the first section of the fourth dielectric material is on the first metallization structure;
the first metallization structure is between the first section of the fourth dielectric material and the second dielectric material;
a fourth layer of the third dielectric material separates the second section of the fourth dielectric material and the third sidewall of the second source or drain body;
the second section of the fourth dielectric material is on the second metallization structure; and
the second metallization structure is between the second section of the fourth dielectric material and the second dielectric material.

15. The apparatus of claim 14, wherein the apparatus is coupled to a host component, and the apparatus is coupled to a power supply through the host component.

16. A method, comprising:
patterning a mask layer over a first stack of first nanoribbons;
growing a first source or drain body on ends of second nanoribbons in a second stack, the first source or drain body comprising a select material;
providing a treatment to surfaces not comprising the select material;
depositing a dielectric material on surfaces comprising the select material and not provided the treatment, including on surfaces of the first source or drain body;
removing a treatment material from the surfaces provided the treatment;
removing the mask layer over the first nanoribbons; and
growing a second source or drain body on ends of the first nanoribbons.

17. The method of claim 16, wherein:
the first stack of first nanoribbons and the second stack of second nanoribbons are separated by less than 30 nm; and
the growing the second source or drain body on the ends of the first nanoribbons grows the second source or drain body to the deposited dielectric material, the first and second source or drain bodies separated by the deposited dielectric material.

18. The method of claim 16, further comprising forming an isolation structure between the first and second source or drain bodies by:
etching an opening between the first and second source or drain bodies; and
depositing an insulator material in the opening between the first and second source or drain bodies, the insulator material on the deposited dielectric material.

19. The method of claim 18, wherein the depositing the insulator material in the opening between the first and second source or drain bodies deposits the insulator material on the deposited dielectric material:
below a first upper surface of the first source or drain body;
below a second upper surface of the second source or drain body;
above a first one of the first nanoribbons immediately below an uppermost one of the first nanoribbons; and
above a first one of the second nanoribbons immediately below an uppermost one of the second nanoribbons.

20. The method of claim 18, further comprising forming first and second contacts on the first and second source or drain bodies by:
removing the deposited dielectric material from an upper surface of the first source or drain body;
depositing a metal on the upper surface of the first source or drain body and on a first sidewall of the isolation structure; and
depositing the metal on an upper surface of the second source or drain body and on a second sidewall of the isolation structure, the second sidewall opposite the first sidewall.
